(19) United States
(12) Patent Application Publication
(10) Pub. No.: US 2026/0039265 A1
(43) Pub. Date: Feb. 5, 2026

(54) AMPLIFIER CIRCUIT

(71) Applicant: ADVANTEST CORPORATION, Tokyo (JP)

(72) Inventor: Takahiro TSUSHIMA, Miyagi (JP)

(21) Appl. No.: 19/211,316

(22) Filed: May 19, 2025

(30) Foreign Application Priority Data
Jul. 30, 2024 (JP) 2024-123673

(51) Int. Cl. H03F 3/45

(52) U.S. Cl. CPC H03F 3/45475

(57) ABSTRACT

Provided is an amplifier circuit including: a unit amplifier, wherein the unit amplifier includes a first transistor in which a first input signal is input to a first control terminal and which generates a first output signal, a second transistor in which a second input signal is input to a second control terminal and which generates a second output signal differential from the first output signal, a third transistor which is provided in parallel with the first transistor and generates a third output signal differential from the first output signal, and a fourth transistor which is provided in parallel with the second transistor and generates a fourth output signal differential from the second output signal, the first and fourth output signals are merged to be output to a first output transmission path, and the second and third output signals are merged to be output to a second output transmission path.

The contents of the following patent application(s) are incorporated herein by reference: NO. 2024-123673 filed in JP on Jul. 30, 2024.

### BACKGROUND

### 1. Technical Field

The present invention relates to an amplifier circuit.

### 2. Related Art

Conventionally, a drive circuit which amplifies two complementary input signals having phases opposite to each other and outputs two complementary output signals having phases opposite to each other is known (see, for example, Patent Document 1). In addition, in an integrated circuit including, in a preceding stage, a feedback amplifier circuit including feedback for returning a part of an output signal to an input side, there is known a semiconductor integrated circuit which suppresses generation of distortion of a data signal and gain peaking of frequency characteristics, which occur in wiring between preceding and subsequent stages (see, for example, Patent Document 2). In addition, a circuit including an Fr doubler circuit is known (see, for example, Patent Document 3).

### PRIOR ART DOCUMENTS

### Patent Documents

Patent Document 1: Japanese Patent Application Publication No. 2018-170705
Patent Document 2: International Publication No. 2012/141008
Patent Document 3: Japanese Translation Publication of a PCT route Patent Application No. 2015-526979

### Non-Patent Documents

Non-Patent Document 1: H. Wakita, et al., “36-GHz-bandwidth quad-channel driver module using compact QFN package for optical coherent systems,” 2015 IEEE 24th Electrical Performance of Electronic Packaging and Systems (EPEPS), San Jose, CA, USA, 2015, Pages 213 to 216.
Non-Patent Document 2: T. Tatsumi, et al., “Development of Electro-Absorption Modulator Driver ICs for 25G/40G Transmission,” SEI Technical Review, no. 74, 2012, Pages 66 to 70.
Non-Patent Document 3: J. B. Beyer, et al., “MESFET Distributed Amplifier Design Guidelines,” IEEE Transactions on Microwave Theory and Techniques, vol. 32, Issue 3, March 1984, Pages 268 to 275.
Non-Patent Document 4: Y. Ayasli, et al., “Capacitively Coupled Traveling-Wave Power Amplifier,” IEEE Transactions on Microwave Theory and Techniques, vol. 32, Issue 12, December 1984, Pages 1704 to 1709.

### BRIEF DESCRIPTION OF THE DRAWINGS

FIG. 1 is a diagram illustrating an example of an amplifier circuit 100 according to an embodiment of the present invention.

FIG. 2 is a circuit diagram illustrating an example of a power amplifier stage 90.

FIG. 3 is a circuit diagram illustrating an example of a unit amplifier 200 in a comparative example.

FIG. 4 is a circuit diagram illustrating an example of a unit amplifier 20 according to the embodiment of the present invention.

FIG. 5A is a small signal equivalent circuit diagram on an input side when the unit amplifier 200 of the comparative example illustrated in FIG. 3 is used.

FIG. 5B is a small signal equivalent circuit diagram on an output side when the unit amplifier 200 of the comparative example illustrated in FIG. 3 is used.

FIG. 6A is a small signal equivalent circuit diagram on an input side when the unit amplifier 20 of the embodiment illustrated in FIG. 4 is used.

FIG. 6B is a small signal equivalent circuit diagram on an output side when the unit amplifier 20 of the embodiment illustrated in FIG. 4 is used.

FIG. 7 is a detailed circuit diagram of the unit amplifier 20 of the embodiment illustrated in FIG. 4.

FIG. 8A is a circuit diagram illustrating a modification of the unit amplifier 20 according to the embodiment.

FIG. 8B is a circuit diagram illustrating an example of an RC circuit 50.

FIG. 8C is a circuit diagram illustrating a specific example of the unit amplifier 20 of FIG. 8A.

FIG. 8D is a detailed circuit diagram of the unit amplifier 20 illustrated in FIG. 8C.

FIG. 9A is a circuit diagram illustrating a modification of a unit configuration section 40 in the unit amplifier 20 illustrated in FIG. 8A.

FIG. 9B is a detailed circuit diagram of the unit amplifier 20 including the unit configuration section 40 illustrated in FIG. 9A.

FIG. 10A is a small signal equivalent circuit diagram on an input side when the unit amplifier 20 of the embodiment illustrated in FIGS. 8A to 8D is used.

FIG. 10B is a small signal equivalent circuit diagram on an input side when the unit amplifier 20 of the embodiment illustrated in FIG. 9A or 9B is used.

FIG. 11A is a circuit diagram illustrating another modification of the unit amplifier 20 according to the embodiment.

FIG. 11B is a detailed circuit diagram of the unit amplifier 20 illustrated in FIG. 11A.

FIG. 12A is a circuit diagram illustrating another modification of the unit amplifier 20 according to the embodiment.

FIG. 12B is a detailed circuit diagram of the unit amplifier 20 illustrated in FIG. 12A.

FIG. 13A is a circuit diagram illustrating another modification of the unit amplifier 20 according to the embodiment.

FIG. 13B is a circuit diagram illustrating another modification of the unit amplifier 20 according to the embodiment.

### DESCRIPTION OF EXEMPLARY EMBODIMENTS

Hereinafter, the invention will be described through embodiments of the invention, but the following embodiments do not limit the present invention according to claims. In addition, not all of the combinations of features described in the embodiments are essential to the solving means of the invention. Note that in the present specification and the diagrams, elements having substantially the same function and architecture are denoted with a same reference sign to omit duplicated descriptions, and illustrations of elements that are not directly related to the present invention will be omitted. Furthermore, in one drawing, elements having the same functions and configurations are denoted by a representative reference numeral, and other reference numerals for the elements may be omitted.

A case where a term such as “same” or “equal” is used in the present specification may include a case where an error due to a variation in manufacturing or the like is included. The error is, for example, within 10%.

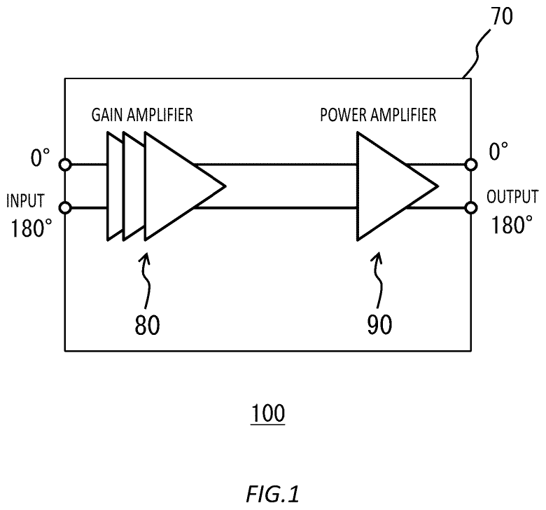

FIG. 1 is a diagram illustrating an example of an amplifier circuit 100 according to an embodiment of the present invention. The amplifier circuit 100 amplifies an input signal and outputs the same. The amplifier circuit 100 may be a high-frequency differential amplifier. The amplifier circuit 100 in FIG. 1 is a fully differential amplifier into which a differential signal is input and which outputs a differential signal. In the present specification, “differential” may mean that phases of signals are different by an angle of 180°. However, the angle may include an error of about 5°. In FIG. 1, one signal of the differential signals has a phase of 0°, and another signal has a phase of 180°.

As an example, in a test apparatus which tests a device to be measured such as a semiconductor apparatus, the amplifier circuit 100 is provided between a signal generator and the device to be measured, and amplifies a high-frequency test signal. The signal generator generates a test signal which is input to the device to be measured. However, an application of the amplifier circuit 100 is not limited to the test apparatus, and the amplifier circuit 100 may be widely used for amplification of a high-frequency signal in a driver of an optical modulator, a transceiver, or the like. The high-frequency differential amplifier is advantageous for in-phase noise removal and thus is used in various apparatuses. The high frequency may be a frequency of 1 GHz or more.

The amplifier circuit 100 includes a block 70. The block 70 of the present example has a gain amplifier stage 80 and a power amplifier stage 90. The gain amplifier stage 80 is mainly used to obtain a gain. The gain amplifier stage 80 may be a variable gain amplifier. The power amplifier stage 90 is used to obtain power of a signal to be output. That is, the gain and the output power can be obtained in the entire block 70 by the gain amplifier stage 80 and the power amplifier stage 90. In addition, since an input capacitance of the block 70 is reduced by dividing the block 70 into the gain amplifier stage 80 and the power amplifier stage 90, it is possible to facilitate design of a pre-stage circuit such as a frequency converter. A distributed amplifier may be used for the power amplifier stage 90. By using the distributed amplifier, a broadband operation and a low input/output return loss can be realized.

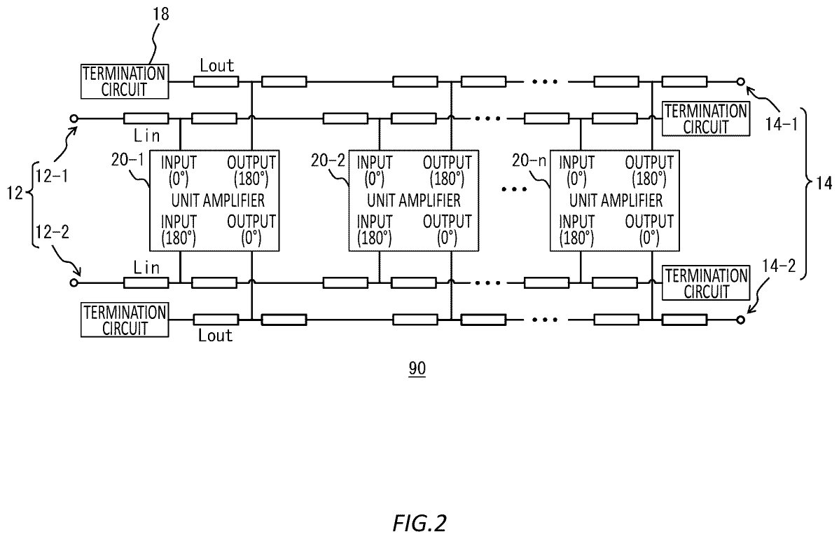

FIG. 2 is a circuit diagram illustrating an example of the power amplifier stage 90. The power amplifier stage 90 of the present example is a distributed amplifier. In the present specification, the power amplifier stage 90 of the high-frequency differential amplifier employing the distributed amplifier may be referred to as a high-frequency differential distributed amplifier. The power amplifier stage 90 of the present example includes a differential input transmission path 12, a differential output transmission path 14, a termination circuit 18, and a unit amplifier 20.

The differential input transmission path 12 includes a first input transmission path 12-1 and a second input transmission path 12-2. An input signal is conveyed to the first input transmission path 12-1, and an input signal differential from the first input transmission path 12-1 is conveyed to the second input transmission path 12-2. In FIG. 2, an inductance component of the differential input transmission path 12 is represented by Lin.

In the power amplifier stage 90, at least one unit amplifier 20 is provided between the differential input transmission path 12 and the differential output transmission path 14. In the power amplifier stage 90 of the present example, n unit amplifiers 20 are provided. A configuration of the unit amplifier 20 will be described later. The n unit amplifiers 20 are provided in parallel with each other between the differential input transmission path 12 and the differential output transmission path 14. The n unit amplifiers 20 may have circuit configurations which are the same as each other.

The differential output transmission path 14 includes a first output transmission path 14-1 and a second output transmission path 14-2. An output signal generated by the unit amplifier 20 is conveyed to the first output transmission path 14-1, and an output signal differential from the first output transmission path 14-1 is conveyed to the second output transmission path 14-2. In FIG. 2, an inductance component of the differential output transmission path 14 is represented by Lout.

An input signal transmitted through the differential input transmission path 12 is sequentially input to the unit amplifiers 20 from a side closer to an input terminal. Circuit parameters are set such that the signals output from the respective unit amplifiers 20 have a same phase in the differential output transmission path 14. Accordingly, the signals output from the respective unit amplifiers 20 are combined in the differential output transmission path 14, and a current is amplified.

The termination circuits 18 are provided at end portions of the differential input transmission path 12 and the differential output transmission path 14. A characteristic impedance of the termination circuit 18 may be set to be equal to a characteristic impedance of the unit amplifier 20. By providing the termination circuit 18, a signal can be transmitted without being reflected in each transmission path. The termination circuit 18 may be a circuit in which a resistor and a capacitor are connected in series as described later, may be an inductance, or may be a transistor. However, the termination circuit 18 may not be provided.

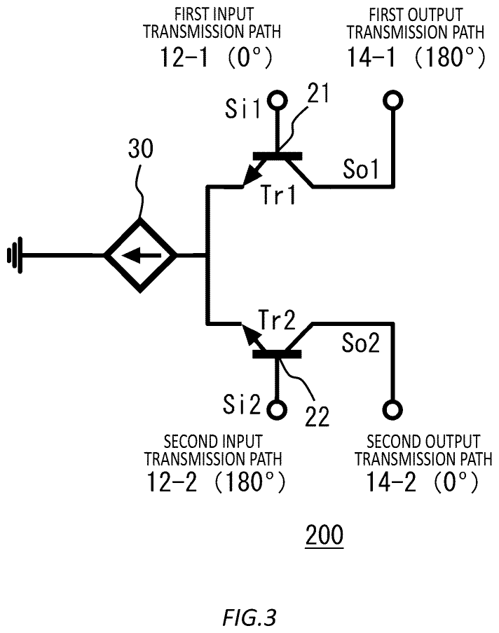

FIG. 3 is a circuit diagram illustrating an example of a unit amplifier 200 in a comparative example. The unit amplifier 200 of the present example includes a first transistor Tr1, a second transistor Tr2, and a current source 30. The first transistor Tr1 and the second transistor Tr2 are connected in parallel to the common current source 30.

The first transistor Tr1 has a first control terminal 21. The first transistor Tr1 of the present example is a bipolar transistor, and the first control terminal 21 is a base terminal. In the first transistor Tr1, a first input signal Si1 is input from the first input transmission path 12-1 to the first control terminal 21, and the first transistor Tr1 generates a first output signal So1. The first output signal So1 is conveyed to the first output transmission path 14-1.

Similarly, the second transistor Tr2 has a second control terminal 22. The second transistor Tr2 of the present example is also a bipolar transistor, and the second control terminal 22 is a base terminal. In the second transistor Tr2, a second input signal Si2 differential from the first input signal Si1 is input from the second input transmission path 12-2 to the second control terminal 22, and the second transistor Tr2 generates a second output signal So2 differential from the second input signal Si2. The second output signal So2 is conveyed to the second output transmission path 14-2.

A half circuit of the high-frequency differential distributed amplifier is equivalent to a single-phase distributed amplifier. Therefore, characteristics of both can be expressed by a same expression. An expression of an output power Po of the single-phase distributed amplifier is shown below.

$${P}_{o} = \frac{1}{2} {I}_{o} {V}_{o} \qquad ( 1 )$$

Here, Vo is an output voltage, and lo is an output current.

The output current lo can be simply expressed by the following expression.

$${I}_{o} = \frac{1}{2} {\sum }_{i = 1}^{n} {g}_{m} {V}_{i} \qquad ( 2 )$$

Here, n is a number of at least one unit amplifier included in a distributed amplifier, gm is a mutual inductance of a transistor, and Vi is an input voltage of an i-th unit amplifier. Note that n may be an optimum number Nopt given from gate loading and drain loading. The optimum number Nopt can be set by a method described in Non-Patent Document 3. When the number n of at least one unit amplifier and the input voltage Vi are constant, the output current lo depends on the mutual inductance gm of the transistor. The mutual inductance gm of the transistor is decided by a transistor size (channel width).

Next, a simple expression of a cutoff frequency fc of the distributed amplifier will be described below.

$${f}_{c} ∼ \frac{1}{π \cdot {C}_{in} \cdot {Z}_{o}} \qquad ( 3 )$$

Here, Cin is an input capacitance of the unit amplifier. When the unit amplifier has the configuration of FIG. 3, the input capacitance Cin is a gate-source capacitance Cgs or a base-emitter capacitance Cn of a transistor Tr. Note that it is assumed that the gate-drain capacitance Cgd or the base-collector capacitance Cμ is sufficiently small and negligible. In many cases, the transistor has a relationship of input capacitance Cin»output capacitance Cout. Therefore, the cutoff frequency fc of the distributed amplifier is dominated by the input capacitance Cin.

According to Expressions 1 and 2, it is necessary to increase the transistor size in order to increase the output power Po. However, when the transistor size is increased, the input capacitance Cin also increases, and thus the cutoff frequency fc is lower than that in Expression 3. That is, there is a trade-off relationship between an output power and a cutoff frequency of the high-frequency differential distributed amplifier.

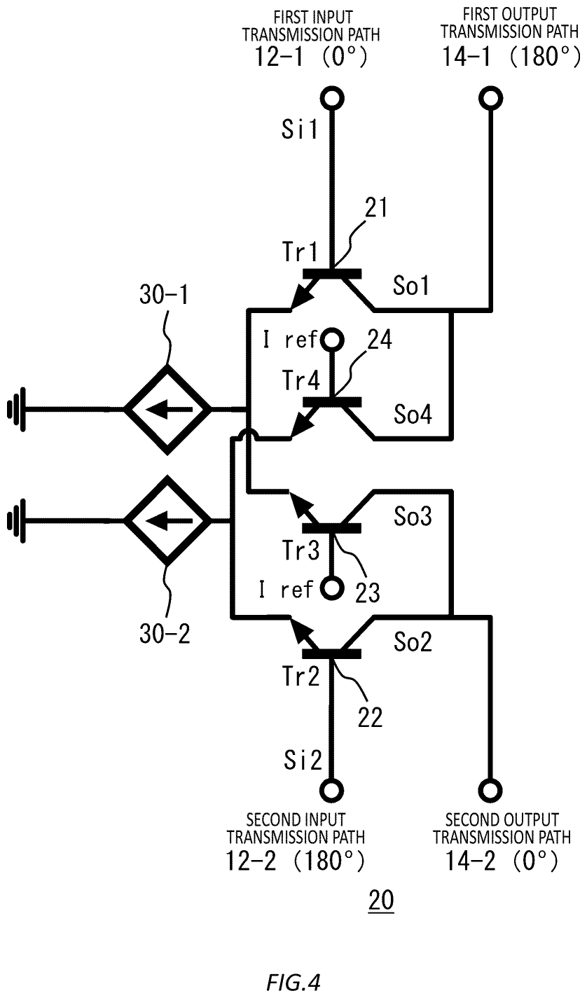

FIG. 4 is a circuit diagram illustrating an example of the unit amplifier 20 according to the embodiment of the present invention. The unit amplifier 20 of the present example includes the first transistor Tr1, the second transistor Tr2, a third transistor Tr3, a fourth transistor Tr4, a first current source 30-1, and a second current source 30-2. Similarly to FIG. 3, each transistor has a control terminal. Each transistor of the present example is a current driven bipolar transistor, but is not limited thereto. Each of the transistors Tr1 to Tr4 may be a voltage driven element such as a MOSFET.

In the first transistor Tr1, the first input signal Si1 is input from the first input transmission path 12-1 to the first control terminal 21, and the first transistor Tr1 generates the first output signal So1. In the second transistor Tr2, the second input signal Si2 is input from the second input transmission path 14-2 to the second control terminal 22, and the second transistor Tr2 generates the second output signal So2 differential from the first output signal So1. The first input signal Si1 and the second input signal Si2 are differential signals. Each signal in the present example is a current, but may be a voltage.

The third transistor Tr3 is provided in parallel with the first transistor Tr1, and generates a third output signal So3 differential from the first output signal So1. The third transistor Tr3 and the first transistor Tr1 are connected in parallel to each other with respect to the common first current source 30-1.

The fourth transistor Tr4 is provided in parallel with the second transistor Tr2, and generates a fourth output signal So4 differential from the second output signal So2. The fourth transistor Tr4 and the second transistor Tr2 are connected in parallel to each other with respect to the common second current source 30-2. The first current source 30-1 and the second current source 30-2 are provided in parallel to each other.

In the unit amplifier 20 of the present example, the first output signal So1 and the fourth output signal So4 are merged to be output to the first output transmission path 14-1. Similarly, the second output signal So2 and the third output signal So3 are merged to be output to the second output transmission path 14-2.

Since the first input signal Si1 and the second input signal Si2 are differential signals, the second transistor Tr2 is turned off when the first transistor Tr1 is turned on. In the present specification, a state where a current flows through each transistor is referred to as on, and a state where no current flows is referred to as off. Since the fourth transistor Tr4 and the second transistor Tr2 are connected to the common second current source 30-2, when the second transistor Tr2 is turned off (the second output signal So2 is 0), the fourth output signal So4 flows through the fourth transistor Tr4. As a result, when the first transistor Tr1 is turned on, the first output signal So1 and the fourth output signal So4 are simultaneously generated, and the current of the signals output to the first output transmission path 14-1 increases (So1+So4). The same applies to the signals (So2+So3) output to the second output transmission path 14-2. That is, the output current lo in Expression 1 increases, and the output power Po can be increased.

A third control terminal 23 of the third transistor Tr3 and a fourth control terminal 24 of the fourth transistor Tr4 are not connected to the differential input transmission path 12, and a signal different from the first input signal Si1 and the second input signal Si2 may be input. A bias signal Iref is input to the third control terminal 23 and the fourth control terminal 24 of the present example without passing through the differential input transmission path 12. The bias signal Iref may be a signal indicating a constant value. The bias signal Iref may be a current or a voltage. The bias signal Iref of the present example is a constant current. When the above-described first transistor Tr1 is turned on, the third transistor Tr3 is also in a state where a current can flow, but since the current from the first transistor Tr1 is large, almost no current flows through the third transistor Tr3, and the third transistor Tr3 is turned off. Similarly, when the second transistor Tr2 is turned on, the fourth transistor Tr4 is also in a state where a current can flow, but since the current from the second transistor Tr2 is large, almost no current flows through the fourth transistor Tr4, and the fourth transistor Tr4 is turned off.

The input capacitances (in the present example, the base-emitter capacitance Ct) of the third transistor Tr3 and the fourth transistor Tr4 are not connected to the differential input transmission path 12. Therefore, the input capacitance Cin (see Expression 3) of the unit amplifier 20 illustrated in FIG. 4 remains unchanged from that of the unit amplifier 200 illustrated in FIG. 3, and the cutoff frequency fc does not decrease. That is, in the unit amplifier 20 of the present example, a trade-off between the output power Po and the cutoff frequency fc can be improved. The transistors Tr1 to Tr4 may have same characteristics such as a size (channel width) and an input capacitance.

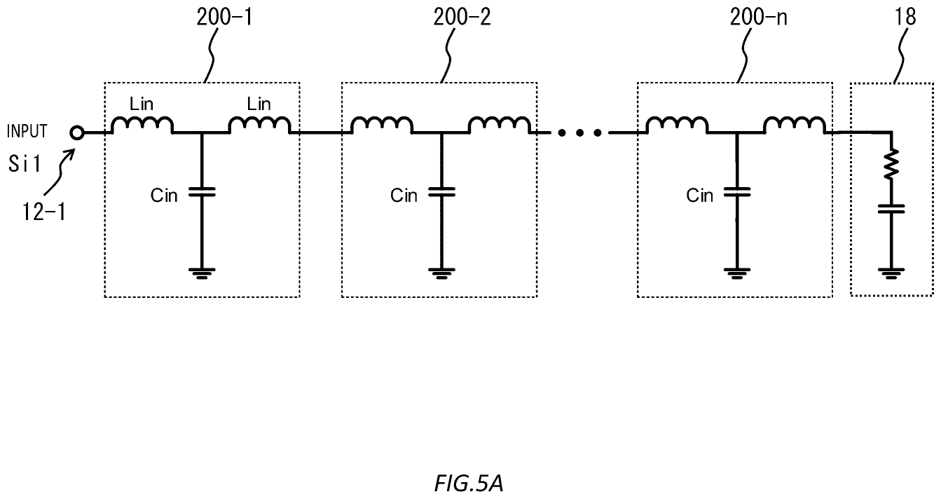

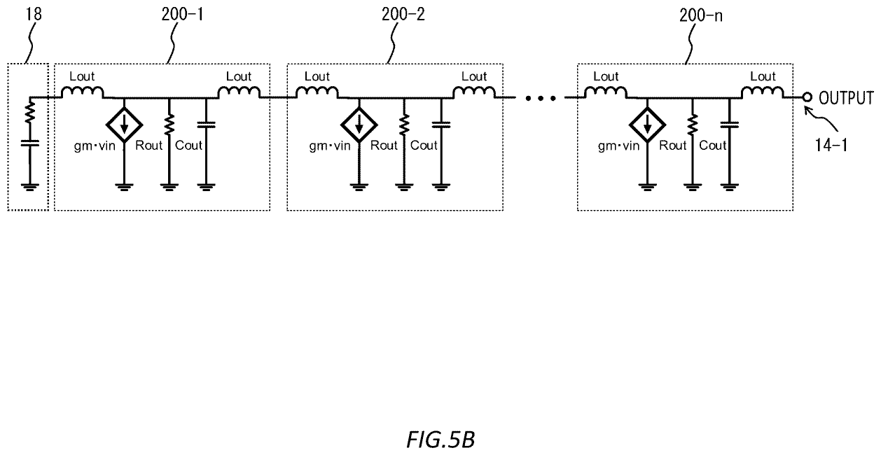

FIG. 5A is a small signal equivalent circuit diagram on an input side when the unit amplifier 200 of the comparative example illustrated in FIG. 3 is used. FIG. 5A illustrates the input capacitance Cin of the unit amplifier 200. Although FIG. 5A illustrates the first input transmission path 12-1 side, the same may apply to the second input transmission path 12-2 side. In FIG. 5A, the unit amplifier 200 includes the inductance component Lin of the first input transmission path 12-1. In addition, the termination circuit 18 of the present example includes a resistor and a capacitor connected in series.

FIG. 5B is a small signal equivalent circuit diagram on an output side when the unit amplifier 200 of the comparative example illustrated in FIG. 3 is used. FIG. 5B illustrates the mutual inductance gm of the transistor of the unit amplifier 200, the output capacitance Cout appearing on the output side, and an output resistance Rout appearing on the output side. In FIG. 5B, the unit amplifier 200 includes the inductance component Lout of the differential output transmission path 14. In addition, the termination circuit 18 of the present example also includes a resistor and a capacitor connected in series.

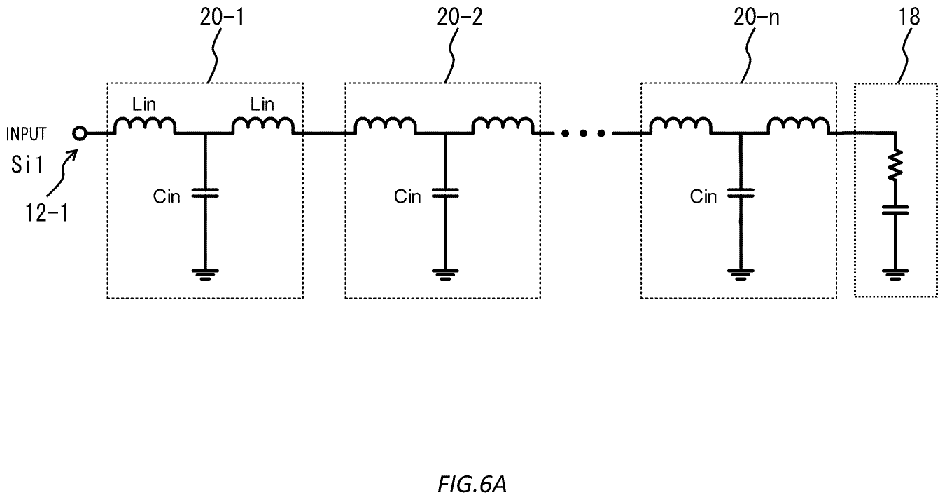

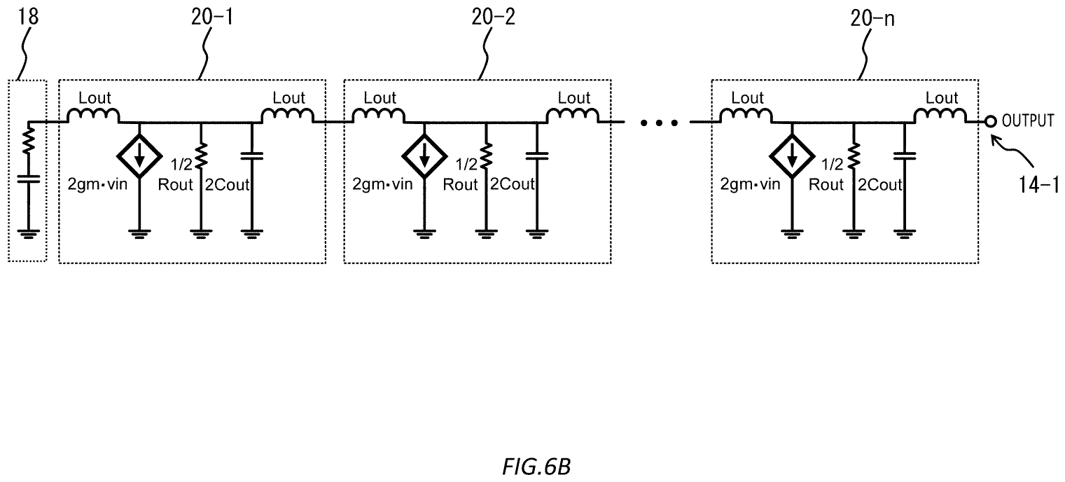

FIG. 6A is a small signal equivalent circuit diagram on an input side when the unit amplifier 20 of the embodiment illustrated in FIG. 4 is used. Reference signs or the like in FIG. 6A are the same as those in FIG. 5A. As described above, since the third control terminal 23 of the third transistor Tr3 and the fourth control terminal 24 of the fourth transistor Tr4 are not connected to the differential input transmission path 12, the input capacitance Cin is the same as that in a case of FIG. 5A.

FIG. 6B is a small signal equivalent circuit diagram on an output side when the unit amplifier 20 of the embodiment illustrated in FIG. 4 is used. Reference signs or the like in FIG. 6B are the same as those in FIG. 5B. Since the unit amplifier 20 of the embodiment includes the third transistor Tr3 and the fourth transistor Tr4, the mutual inductance gm of the transistor included in the unit amplifier 20 is twice (2 gm) as compared with the unit amplifier 200 of the comparative example. That is, the output power can be doubled while maintaining the cutoff frequency fc. Note that in FIG. 6B, the output resistance Rout is halved and the output capacitance Cout is doubled as compared with FIG. 5B, but influences thereof are negligible since the input capacitance Cin is a dominant term with respect to the cutoff frequency fc as described above.

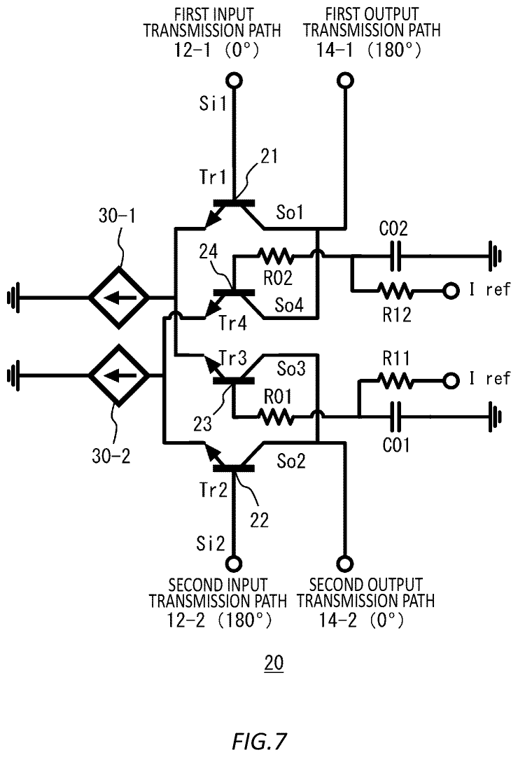

FIG. 7 is a detailed circuit diagram of the unit amplifier 20 of the embodiment illustrated in FIG. 4. Description of a configuration similar to that of FIG. 4 is omitted. The unit amplifier 20 of the present example includes a first series resistor R01, a first series capacitor C01, and a first parallel resistor R11.

The first series resistor R01 is connected in series with the third control terminal 23 of the third transistor Tr3. The first series capacitor C01 is connected in series with the first series resistor R01 between the first series resistor R01 and a ground terminal. The first parallel resistor R11 is provided in parallel with the first series capacitor C01, and the bias signal Iref is input thereto. The first parallel resistor R11 may be connected in series with the first series resistor R01.

Accordingly, a high-frequency signal flows to the first series capacitor C01 side, and a terminal to which the bias signal Iref is input can be shielded. A resistance value of the first parallel resistor R11 may be larger than a resistance value of the first series resistor R01.

The unit amplifier 20 may further include a second series resistor R02, a second series capacitor C02, and a second parallel resistor R12. The second series resistor R02 of the present example is connected in series with the fourth control terminal 24 of the fourth transistor Tr4. The second series capacitor C02 is connected in series with the second series resistor R02 between the second series resistor R02 and the ground terminal. The second parallel resistor R12 is provided in parallel with the second series capacitor C02, and the bias signal Iref is input thereto. The second parallel resistor R12 may be connected in series with the second series resistor R02.

Accordingly, a high-frequency signal flows to the second series capacitor C02 side, and a terminal to which the bias signal Iref is input can be shielded. A resistance value of the second parallel resistor R12 may be larger than a resistance value of the second series resistor R02.

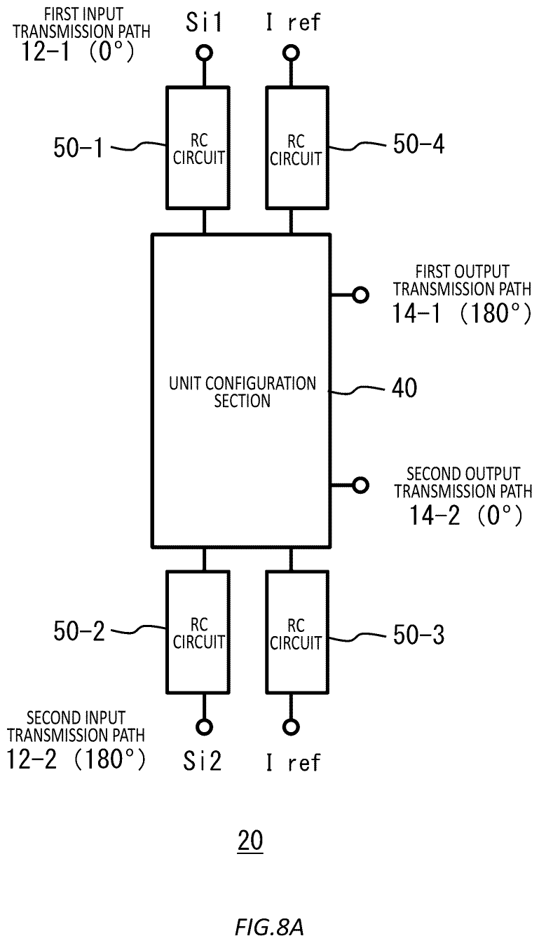

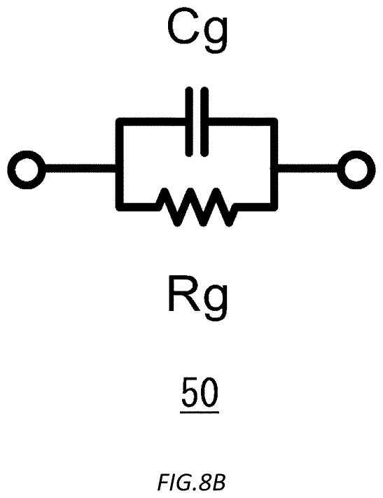

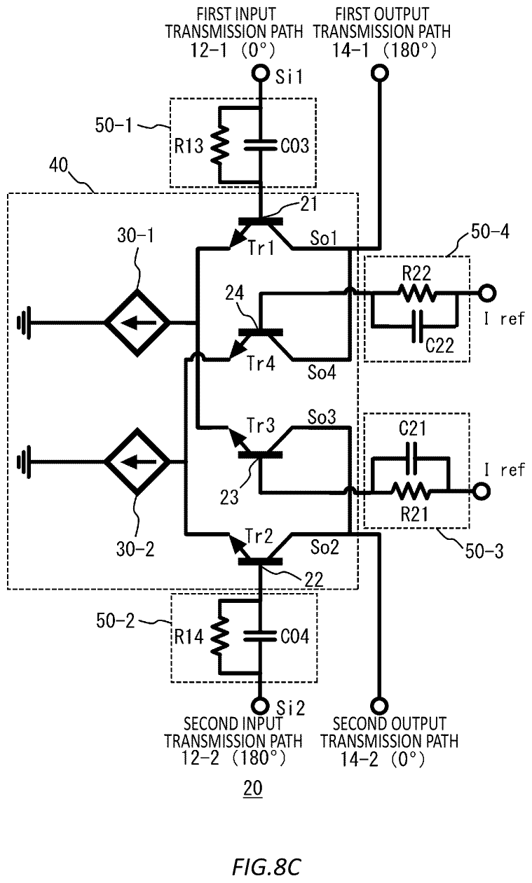

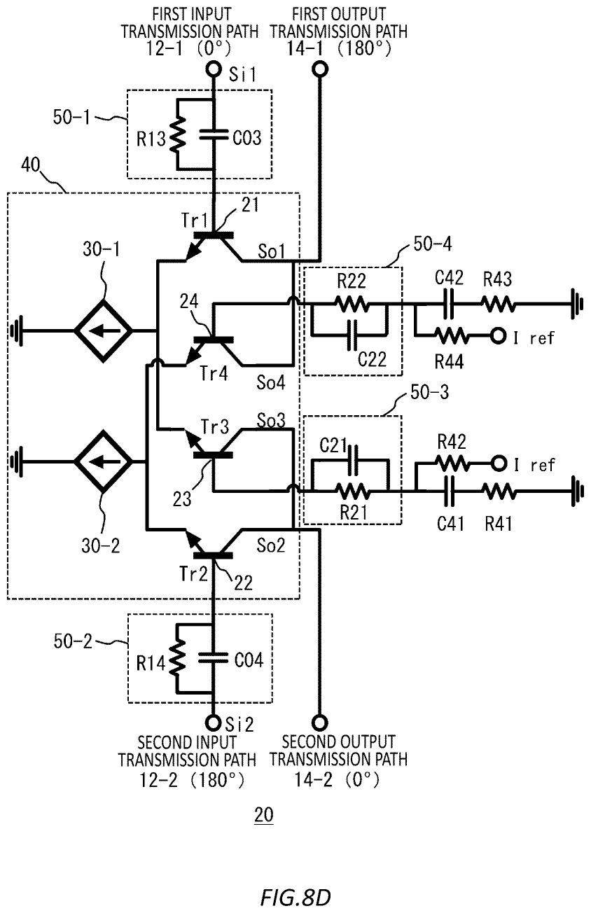

FIG. 8A is a circuit diagram illustrating a modification of the unit amplifier 20 according to the embodiment. The unit amplifier 20 of the present example includes a unit configuration section 40 and an RC circuit 50. The unit configuration section 40 may include either the unit amplifier 20 illustrated in FIG. 4 or the unit amplifier 20 illustrated in FIG. 7.

The unit amplifier 20 of the present example includes four RC circuits 50. The first input signal Si1 is input from the first input transmission path 12-1 to an RC circuit 50-1. The second input signal Si2 is input from the second input transmission path 12-1 to an RC circuit 50-2. The bias signal Iref is input to an RC circuit 50-3 and an RC circuit 50-4.

FIG. 8B is a circuit diagram illustrating an example of the RC circuit 50. The RC circuit 50 includes a resistor Rg and a capacitor Cg connected in parallel.

FIG. 8C is a circuit diagram illustrating a specific example of the unit amplifier 20 of FIG. 8A. The unit configuration section 40 of the present example has a same structure as the unit amplifier 20 illustrated in FIG. 4. Description of a configuration similar to that of FIG. 4 is omitted. The unit amplifier 20 of the present example includes a third series capacitor C03 and a fourth series capacitor C04. The third series capacitor C03 is included in the RC circuit 50-1, and the fourth series capacitor C04 is included in the RC circuit 50-2.

The third series capacitor C03 is connected in series with the first control terminal 21 of the first transistor Tr1. The fourth series capacitor C04 is connected in series with the second control terminal 22 of the second transistor Tr2. When the capacitances are connected in series, a combined capacitance decreases. In a case of the present example, since a combined capacitance of the input capacitance (for example, the base-emitter capacitance Cn) of the first transistor Tr1 and the third series capacitor C03 becomes the input capacitance Cin of the unit amplifier 20, the input capacitance Cin decreases. As a result, a size of the first transistor Tr1 can be increased or a number of at least one unit amplifier 20 can be increased while maintaining the cutoff frequency fc. The same applies to the second transistor Tr2 and the fourth series capacitor C04.

The input capacitance of the first transistor Tr1 may be equal to a capacitance of the third series capacitor C03. Similarly, the input capacitance of the second transistor Tr2 may be equal to a capacitance of the fourth series capacitor C04. According to an expression of a combined capacitance when capacitances are connected in series, a value of the combined capacitance is minimized in a case of the above relationship. That is, the input capacitance Cin can be minimized.

The unit amplifier 20 may further include a third parallel resistor R13 and a fourth parallel resistor R14. The third parallel resistor R13 is connected in parallel with the third series capacitor C03. The fourth parallel resistor R14 is connected in parallel with the fourth series capacitor C04. The first input signal Si1 is input to an end portion of the third parallel resistor R13 and the third series capacitor C03 on a side opposite to the first control terminal 21. The second input signal Si2 is input to a terminal of the fourth parallel resistor R14 and the fourth series capacitor C04 on a side opposite to the second control terminal 22.

Since the capacitor does not convey a DC (direct current) signal, the third series capacitor C03 does not convey the first input signal Si1 of DC, and the fourth series capacitor C04 does not convey the second input signal Si2 of DC. The third parallel resistor R13 and the fourth parallel resistor R14 are further provided, so that an input signal of DC can be conveyed.

An impedance of the third parallel resistor R13 at a high frequency among operating frequencies (for example, an upper limit frequency of the operating frequency defined in the specification) may be 10 times or more, 100 times or more, or 1000 times or more larger than an impedance of the third series capacitor C03. An impedance of the fourth parallel resistor R14 at a high frequency among operating frequencies used may be 10 times or more, 100 times or more, or 1000 times or more larger than an impedance of the fourth series capacitor C04. The high frequency may be 1 GHZ, 10 GHZ, 20 GHz, or 100 GHz or more.

The unit amplifier 20 may further include a first connection resistor R21 and a second connection resistor R22. The first connection resistor R21 is connected to the third control terminal 23 of the third transistor Tr3. The second connection resistor R22 is connected to the fourth control terminal 24 of the fourth transistor Tr4. Accordingly, circuit imbalance in each of the transistors Tr1 to Tr4 is improved, and the characteristics can be improved.

The unit amplifier 20 may further include a first connection capacitor C21 and a second connection capacitor C22. The first connection capacitor C21 is connected to the third control terminal 23 of the third transistor Tr3. The second connection capacitor C22 is connected to the fourth control terminal 24 of the fourth transistor Tr4. Accordingly, circuit imbalance in each of the transistors Tr1 to Tr4 is improved, and the characteristics can be improved.

The first connection resistor R21 and the first connection capacitor C21 of the present example are connected in parallel between the third control terminal 23 and a terminal to which the bias signal Iref is input. The second connection resistor R22 and the second connection capacitor C22 of the present example are connected in parallel between the fourth control terminal 24 and a terminal to which the bias signal Iref is input. The third parallel resistor R13 and the third series capacitor C03 correspond to the RC circuit 50-1, the fourth parallel resistor R14 and the fourth series capacitor C04 correspond to the RC circuit 50-2, the first connection resistor R21 and the first connection capacitor C21 correspond to the RC circuit 50-3, and the second connection resistor R22 and the second connection capacitor C22 correspond to the RC circuit 50-4.

FIG. 8D is a detailed circuit diagram of the unit amplifier 20 illustrated in FIG. 8C.

Description of a configuration similar to that of FIG. 8C is omitted. The unit amplifier 20 of the present example includes a first additional capacitor C41, a first additional resistor R41, a second additional resistor R42, a second additional capacitor C42, a third additional resistor R43, and a fourth additional resistor R44.

The first additional capacitor C41 and the first additional resistor R41 are connected in series between the first connection resistor R21 and the first connection capacitor C21, and the ground terminal. The second additional resistor R42 is connected in parallel with the first additional capacitor C41 and the first additional resistor R41, and the bias signal Iref is input thereto. A resistance value of the second additional resistor R42 may be larger than resistance values of the first connection resistor R21 and the first additional resistor R41. Accordingly, a high-frequency signal flows to the first additional capacitor C41 side, and a terminal to which the bias signal Iref is input can be shielded.

The second additional capacitor C42 and the third additional resistor R43 are connected in series between the second connection resistor R22 and the second connection capacitor C22, and the ground terminal. The fourth additional resistor R44 is connected in parallel with the second additional capacitor C42 and the third additional resistor R43, and the bias signal Iref is input thereto. A resistance value of the fourth additional resistor R44 may be larger than resistance values of the second connection resistor R22 and the third additional resistor R43. Accordingly, a high-frequency signal flows to the second additional capacitor C42 side, and a terminal to which the bias signal Iref is input can be shielded.

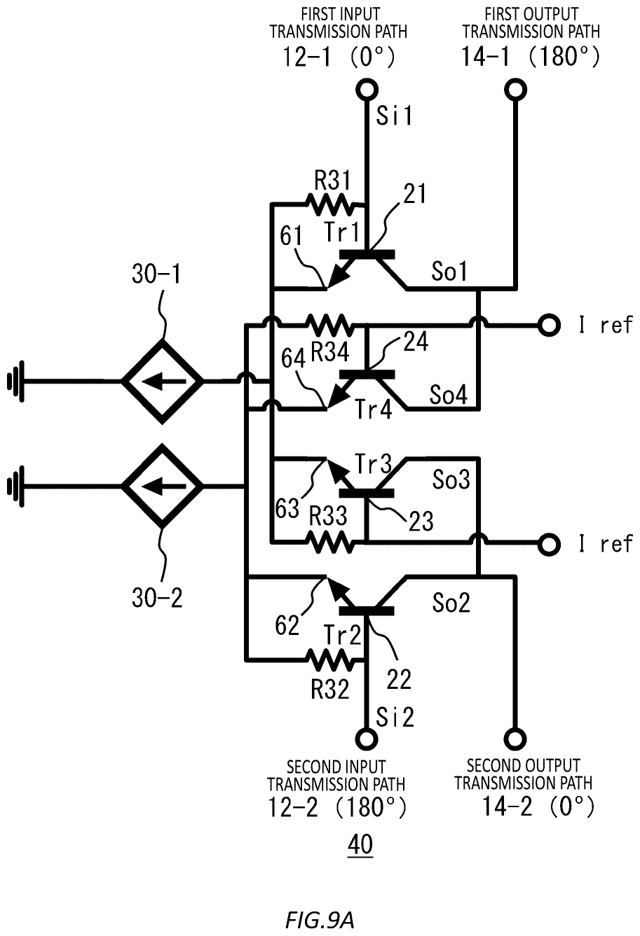

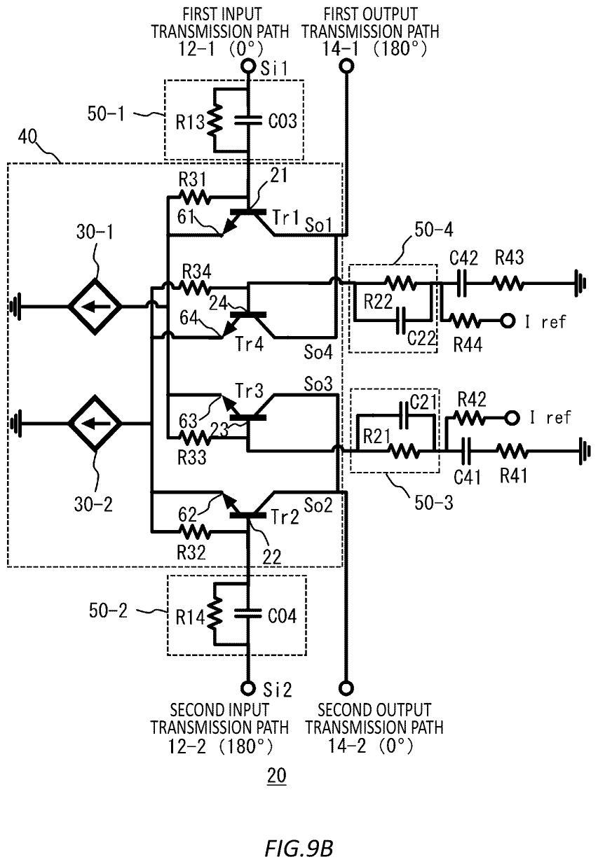

FIG. 9A is a circuit diagram illustrating a modification of the unit configuration section 40 in the unit amplifier 20 illustrated in FIG. 8A. The unit amplifier 20 of the present example is different from those of other modifications in that the unit configuration section 40 includes a first bypass resistor R31 and a second bypass resistor R32.

The first bypass resistor R31 is connected between the first control terminal 21 of the first transistor Tr1 and a first grounded terminal 61. The second bypass resistor R32 is connected between the second control terminal 22 of the second transistor Tr2 and a second grounded terminal 62. The grounded terminal may be an emitter terminal or a source terminal of the transistor.

The unit amplifier 20 may include a third bypass resistor R33 and a fourth bypass resistor R34 in the unit configuration section 40. The third bypass resistor R33 in the present example is connected between the third control terminal 23 of the third transistor Tr3 and a third grounded terminal 63. The fourth bypass resistor R34 is connected between the fourth control terminal 24 of the fourth transistor Tr4 and a fourth grounded terminal 64.

FIG. 9B is a detailed circuit diagram of the unit amplifier 20 including the unit configuration section 40 illustrated in FIG. 9A. The unit amplifier 20 of the present example has a configuration in which the circuit configuration illustrated in FIG. 8D and the unit configuration section 40 illustrated in FIG. 9A are combined. The circuit configurations illustrated in FIGS. 8A to 8D and the circuit configuration illustrated in FIG. 9A may be arbitrarily combined. For example, in the unit configuration section 40 of the unit amplifier 20 including the third series capacitor C03, the third parallel resistor R13, the fourth series capacitor C04, and the fourth parallel capacitor R14, the first bypass resistor R31 and the second bypass resistor R32 may be provided.

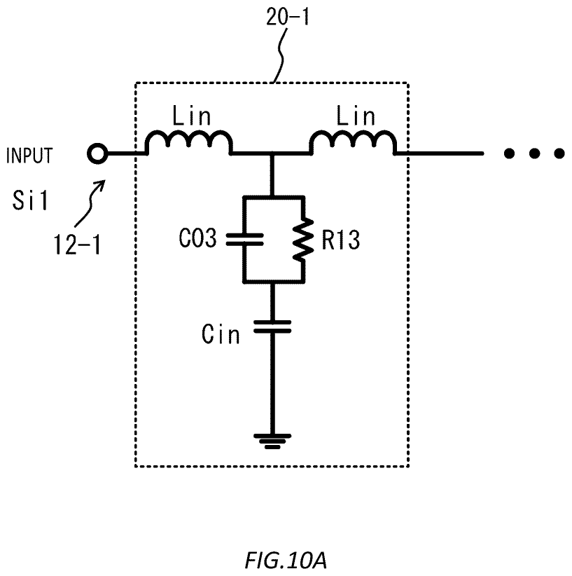

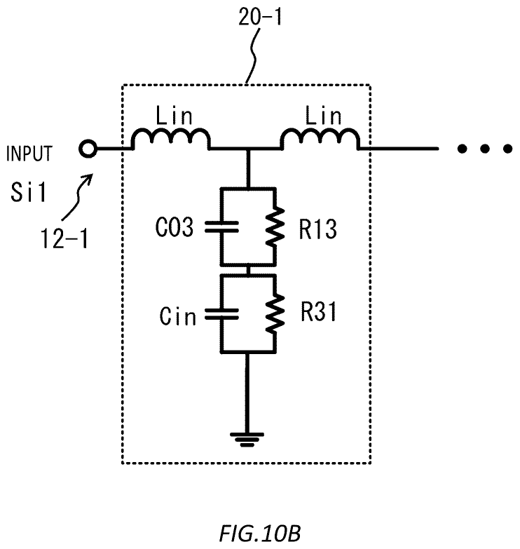

FIG. 10A is a small signal equivalent circuit diagram on an input side when the unit amplifier 20 of the embodiment illustrated in FIGS. 8A to 8D is used. Description of a configuration similar to those of FIGS. 5A and 6A is omitted. Since the unit amplifier 20 of the present example includes the third series capacitor C03 and the third parallel resistor R13, circuit elements thereof appear on the input side.

As described above, the capacitance of the third series capacitor C03 is set to a same value as the input capacitance Cin of the first transistor in many cases. At a high frequency, the impedance of the third series capacitor C03 is sufficiently smaller than the impedance of the third parallel resistor R13, and the third parallel resistor R13 is negligible. At this time, since the third series capacitor C03 and the input capacitance Cin of the first transistor are connected in series, a voltage of the input signal Si1 is divided in half and applied to the third series capacitor C03 and the input capacitance Cin of the first transistor.

On the other hand, at a low frequency (for example, MHz or less), the impedance of the third series capacitor C03 is sufficiently larger than the impedance of the third parallel resistor R13. Therefore, the voltage applied to the input capacitance Cin of the first transistor increases due to a voltage division relationship. That is, a value of the input voltage applied to the input capacitance Cin of the first transistor changes at a low frequency and a high frequency, so that a gain flatness of the amplifier deteriorates. That is, a lower limit of the operating frequency is determined by an impedance of the RC circuit 50.

FIG. 10B is a small signal equivalent circuit diagram on an input side when the unit amplifier 20 of the embodiment illustrated in FIG. 9A or 9B is used. The unit amplifier 20 of the present example has the bypass resistor R31, whereby a series connection of RC parallel circuits is formed. A resistance value of the third parallel resistor R13 may be equal to a resistance value of the first bypass resistor R31. In this case, even at a low frequency, the voltage of the input signal Si1 is divided in half and applied to the third parallel resistor R13 and the first bypass resistor R31, whereby the gain flatness is improved. That is, an effect of providing the RC circuit 50 can be obtained from DC (0 Hz).

The second input transmission path 12-2 side may have a similar configuration. That is, a resistance value of the fourth parallel resistor R14 may be equal to a resistance value of the second bypass resistor R32. Accordingly, an effect similar to that described above can be obtained. In addition, a resistance value of the third bypass resistor R33 and a resistance value of the fourth bypass resistor R34 may also be equal to the resistance values of the first bypass resistor R31 and the second bypass resistor R32. Accordingly, the circuit imbalance in each transistor is improved, and the characteristics can be improved.

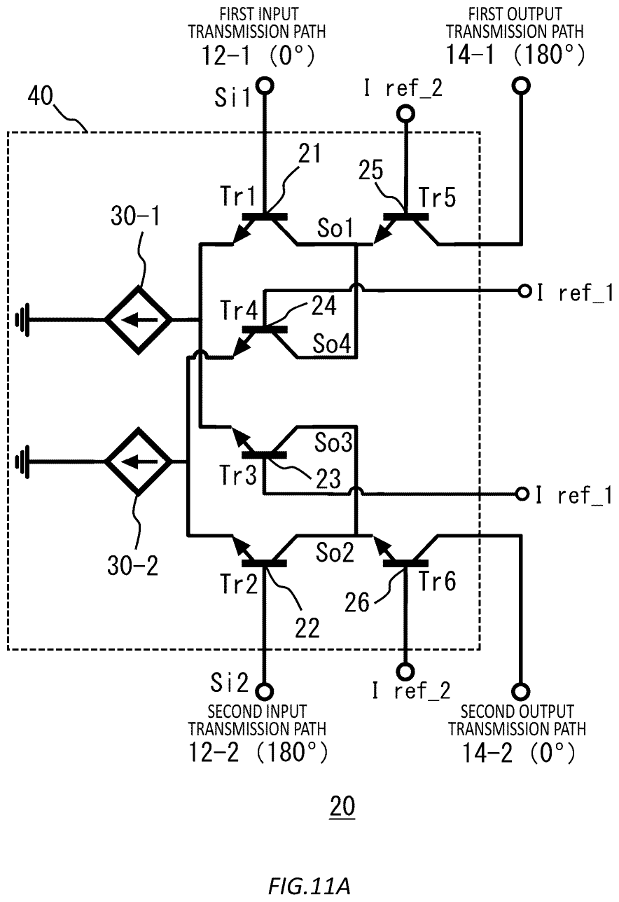

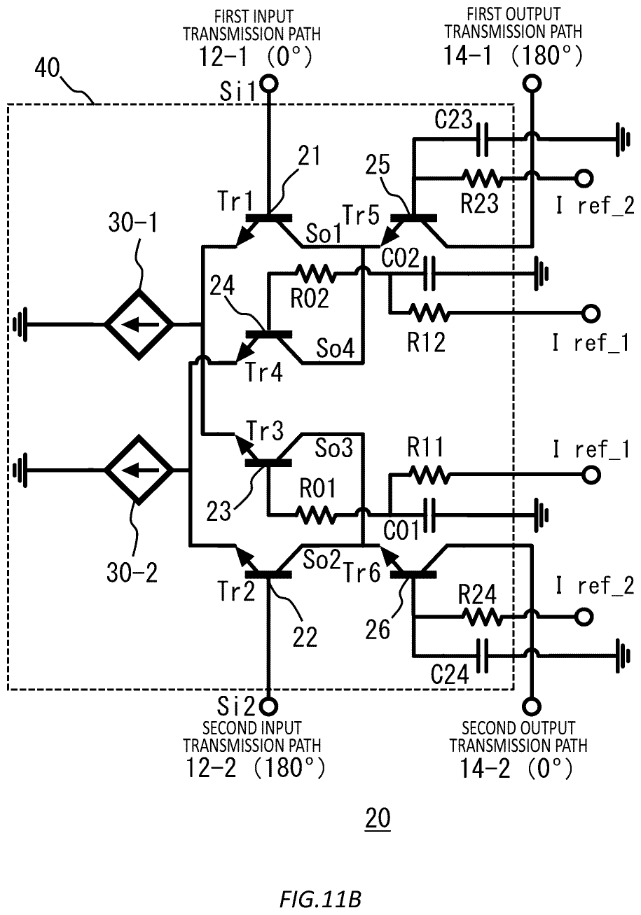

FIG. 11A is a circuit diagram illustrating another modification of the unit amplifier 20 according to the embodiment. The unit amplifier 20 of the present example is different from the unit amplifier 20 of FIG. 4 in including a fifth transistor Tr5 and a sixth transistor Tr6.

The fifth transistor Tr5 is connected between the first transistor Tr1 and the fourth transistor Tr4, and the first output transmission path 14-1. The sixth transistor Tr6 is connected between the second transistor Tr2 and the third transistor Tr3, and the second output transmission path 14-2. Accordingly, an influence of a mirror effect can be reduced, whereby the operating frequency can be extended to a higher frequency side.

A first bias signal Iref_1 is input to the third control terminal 23 of the third transistor Tr3 and the fourth control terminal 24 of the fourth transistor Tr4 of the present example. The first bias signal Iref_1 may be the same as the bias signal Iref illustrated in FIG. 4 or the like. A second bias signal Iref_2 is input to a fifth control terminal 25 of the fifth transistor Tr5 and a sixth control terminal 26 of the sixth transistor Tr6 of the present example. The second bias signal Iref_2 may be a signal indicating a constant value. The second bias signal Iref_2 may be a current or a voltage. The second bias signal Iref_2 of the present example is a constant current. The second bias signal Iref_2 may be the same as the first bias signal Iref_1.

FIG. 11B is a detailed circuit diagram of the unit amplifier 20 illustrated in FIG. 11A. The unit amplifier 20 of the present example further includes a third connection resistor R23, a third connection capacitor C23, a fourth connection resistor R24, and a fourth connection capacitor C24. The third connection resistor R23 is connected to the fifth control terminal 25 of the fifth transistor Tr5. The second bias signal Iref_2 may be input to another end of the third connection resistor R23. The third connection capacitor C23 is connected to the fifth control terminal 25 of the fifth transistor Tr5. Another end of the third connection capacitor C23 may be connected to the ground terminal. Accordingly, a high-frequency signal flows to the third connection capacitor C23 side, and a terminal to which the second bias signal Iref_2 is input can be shielded.

The fourth connection resistor R24 is connected to the sixth control terminal 26 of the sixth transistor Tr6. The second bias signal Iref_2 may be input to another end of the fourth connection resistor R24. The fourth connection capacitor C24 is connected to the sixth control terminal 26 of the sixth transistor Tr6. Another end of the fourth connection capacitor C24 may be connected to the ground terminal. Accordingly, a high-frequency signal flows to the fourth connection capacitor C24 side, and a terminal to which the second bias signal Iref_2 is input can be shielded.

Similarly to FIG. 7, the unit amplifier 20 may include the first series resistor R01, the first series capacitor C01, the first parallel resistor R11, the second series resistor R02, the second series capacitor C02, and the second parallel resistor R12. In that case, the first bias signal Iref_1 may be input to the first parallel resistor R11 and the second parallel resistor R12.

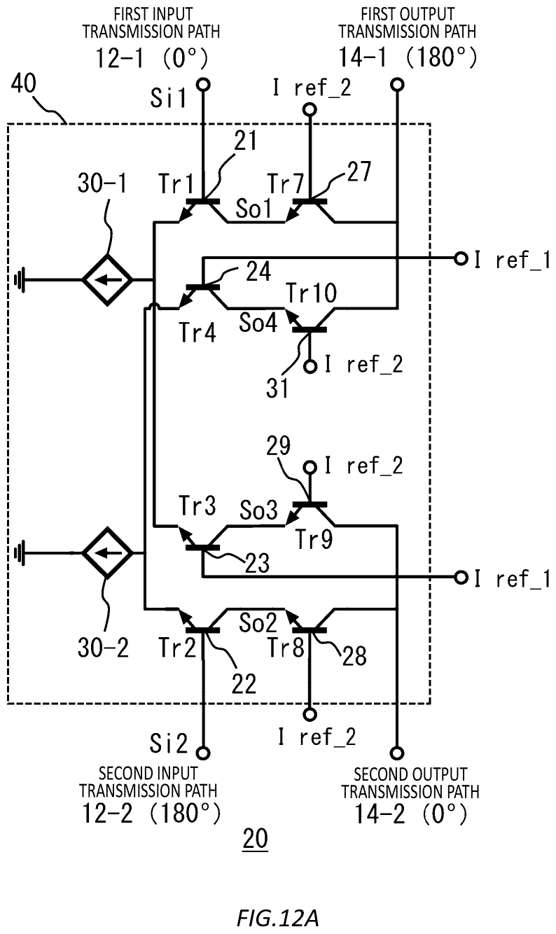

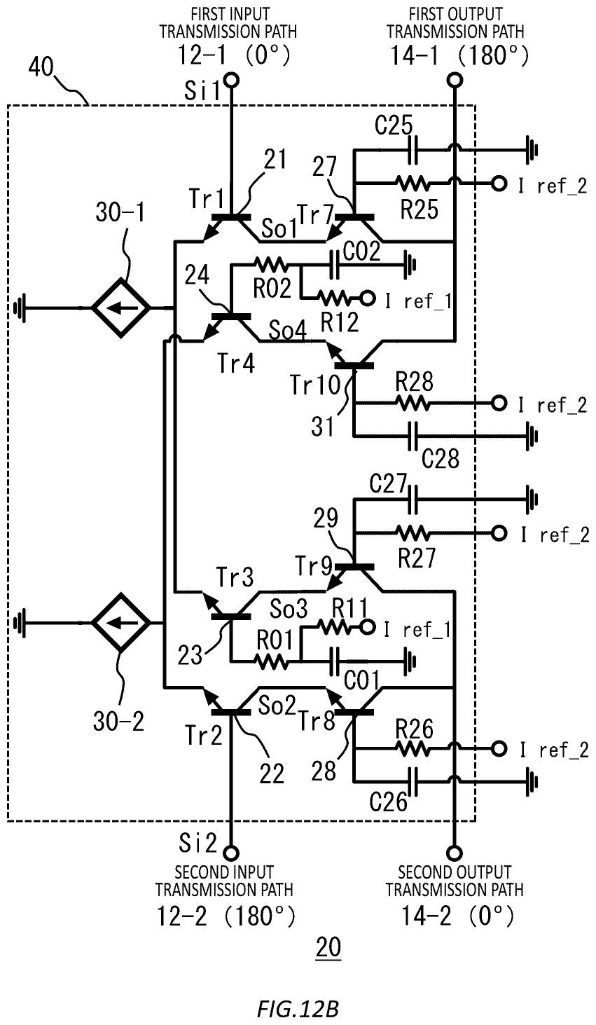

FIG. 12A is a circuit diagram illustrating another modification of the unit amplifier 20 according to the embodiment. The unit amplifier 20 of the present example is different from the unit amplifier 20 of FIG. 4 in including a seventh transistor Tr7, an eighth transistor Tr8, a ninth transistor Tr9, and a tenth transistor Tr10.

The seventh transistor Tr7 is connected between the first transistor Tr1 and the first output transmission path 14-1. The eighth transistor Tr8 is connected between the second transistor Tr2 and the second output transmission path 14-2. The ninth transistor Tr9 is connected between the third transistor Tr3 and the second output transmission path 14-2. The tenth transistor Tr10 is connected between the fourth transistor Tr4 and the first output transmission path 14-1.

Even with such a configuration, since the influence of the mirror effect can be reduced, whereby the operating frequency can be extended to a higher frequency side. The second bias signal Iref_2 may be input to a seventh control terminal 27 of the seventh transistor Tr7, an eighth control terminal 28 of the eighth transistor Tr8, a ninth control terminal 29 of the ninth transistor Tr9, and a tenth control terminal 31 of the tenth transistor Tr10.

FIG. 12B is a detailed circuit diagram of the unit amplifier 20 illustrated in FIG. 12A. The unit amplifier 20 of the present example further includes a fifth connection resistor R25, a fifth connection capacitor C25, a sixth connection resistor R26, a sixth connection capacitor C26, a seventh connection resistor R27, a seventh connection capacitor C27, an eighth connection resistor R28, and an eighth connection capacitor C28.

The fifth connection resistor R25 is connected to the seventh control terminal 27 of the seventh transistor Tr7. The second bias signal Iref_2 may be input to another end of the fifth connection resistor R25. The fifth connection capacitor C25 is connected to the seventh control terminal 27 of the seventh transistor Tr7. Another end of the fifth connection capacitor C25 may be connected to the ground terminal.

The sixth connection resistor R26 is connected to the eighth control terminal 28 of the eighth transistor Tr8. The second bias signal Iref_2 may be input to another end of the sixth connection resistor R26. The sixth connection capacitor C26 is connected to the eighth control terminal 28 of the eighth transistor Tr8. Another end of the sixth connection capacitor C26 may be connected to the ground terminal.

The seventh connection resistor R27 is connected to the ninth control terminal 29 of the ninth transistor Tr9. The second bias signal Iref_2 may be input to another end of the seventh connection resistor R27. The seventh connection capacitor C27 is connected to the ninth control terminal 29 of the ninth transistor Tr9. Another end of the seventh connection capacitor C27 may be connected to the ground terminal.

The eighth connection resistor R28 is connected to the tenth control terminal 31 of the tenth transistor Tr10. The second bias signal Iref_2 may be input to another end of the eighth connection resistor R28. The eighth connection capacitor C28 is connected to the tenth control terminal 31 of the tenth transistor Tr10. Another end of the eighth connection capacitor C28 may be connected to the ground terminal. Accordingly, a high-frequency signal flows to each connection capacitor side, and a terminal to which the second bias signal Iref_2 is input can be shielded.

Similarly to FIG. 7, the unit amplifier 20 may include the first series resistor R01, the first series capacitor C01, the first parallel resistor R11, the second series resistor R02, the second series capacitor C02, and the second parallel resistor R12. In that case, the first bias signal Iref_1 may be input to the first parallel resistor R11 and the second parallel resistor R12.

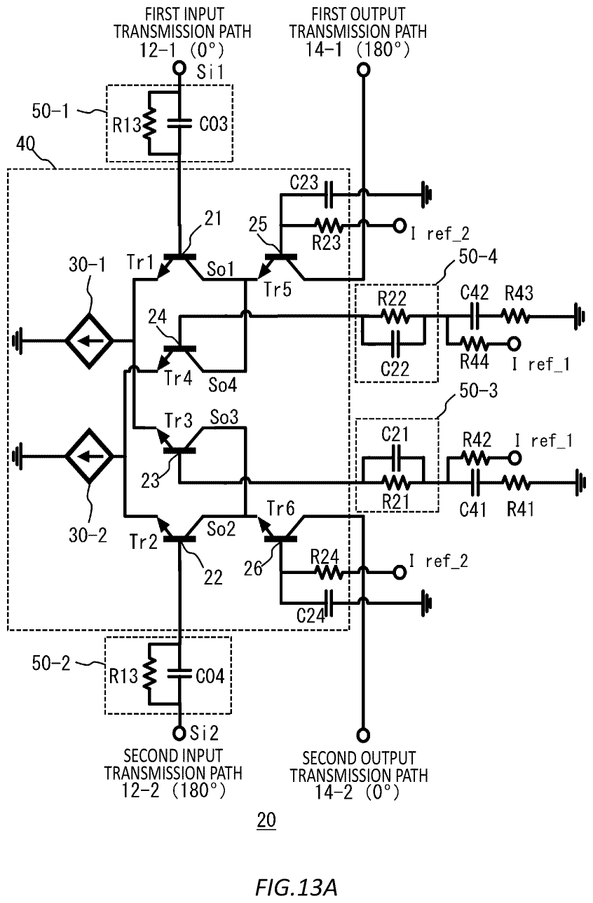

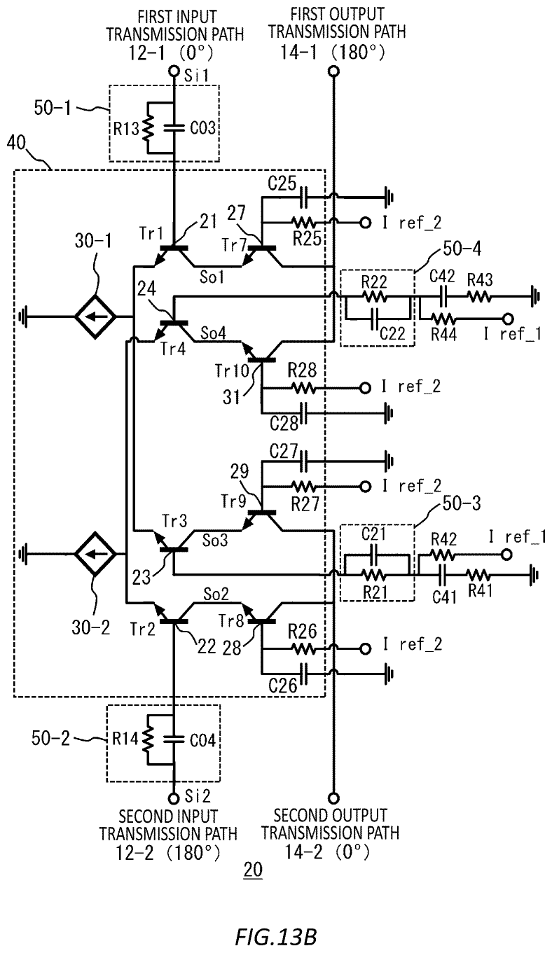

FIG. 13A is a circuit diagram illustrating another modification of the unit amplifier 20 according to the embodiment. The modifications illustrated in FIGS. 8A to 8D and the modifications illustrated in FIGS. 11A and 11B may be arbitrarily combined. For example, the unit amplifier 20 of FIG. 11A or 11B may be adopted as the unit configuration section 40 of FIG. 8A. In addition, a combination illustrated in FIG. 13A may be adopted. Accordingly, effects of respective modifications can be obtained. Note that in each combination, the bypass resistors illustrated in FIGS. 9A and 9B may be provided.

FIG. 13B is a circuit diagram illustrating another modification of the unit amplifier 20 according to the embodiment. The modifications illustrated in FIGS. 8A to 8D and the modifications illustrated in FIGS. 12A and 12B may be arbitrarily combined. For example, the unit amplifier 20 of FIG. 12A or 12B may be adopted as the unit configuration section 40 of FIG. 8A. In addition, a combination illustrated in FIG. 13B may be adopted. Accordingly, effects of respective modifications can be obtained. Note that in each combination, the bypass resistors illustrated in FIGS. 9A and 9B may be provided.

While the embodiments of the present invention have been described, the technical scope of the invention is not limited to the above-described embodiments. It is apparent to persons skilled in the art that various alterations and improvements can be added to the above-described embodiments. It is also apparent from the scope of the claims that the embodiments added with such alterations or improvements can be included in the technical scope of the invention.

What is claimed is:

1. An amplifier circuit comprising:
a differential input transmission path which includes a first input transmission path and a second input transmission path;
a differential output transmission path which includes a first output transmission path and a second output transmission path; and
at least one unit amplifier which is provided between the differential input transmission path and the differential output transmission path, wherein
the unit amplifier includes a first transistor in which a first input signal is input from the first input transmission path to a first control terminal and which generates a first output signal,
a second transistor in which a second input signal is input from the second input transmission path to a second control terminal and which generates a second output signal differential from the first output signal,
a third transistor which is provided in parallel with the first transistor and generates a third output signal differential from the first output signal, and
a fourth transistor which is provided in parallel with the second transistor and generates a fourth output signal differential from the second output signal, and
the first output signal and the fourth output signal are merged to be output to the first output transmission path, and the second output signal and the third output signal are merged to be output to the second output transmission path.

2. The amplifier circuit according to claim 1, wherein
a bias signal is input to a third control terminal of the third transistor and a fourth control terminal of the fourth transistor without passing through the differential input transmission path.

3. The amplifier circuit according to claim 2, wherein
the unit amplifier further includes a first series resistor which is connected in series with the third control terminal of the third transistor,
a first series capacitor which is connected in series with the first series resistor between the first series resistor and a ground terminal, and
a first parallel resistor which is provided in parallel with the first series capacitor and to which the bias signal is input.

4. The amplifier circuit according to claim 2, wherein
the unit amplifier further includes a second series resistor which is connected in series with the fourth control terminal of the fourth transistor,
a second series capacitor which is connected in series with the second series resistor between the second series resistor and a ground terminal, and
a second parallel resistor which is provided in parallel with the second series capacitor and to which the bias signal is input.

5. The amplifier circuit according to claim 1, wherein
the unit amplifier further includes
a third series capacitor which is connected in series with the first control terminal of the first transistor, and
a fourth series capacitor which is connected in series with the second control terminal of the second transistor.

6. The amplifier circuit according to claim 5, wherein
an input capacitance of the first transistor is equal to a capacitance of the third series capacitor, and
an input capacitance of the second transistor is equal to a capacitance of the fourth series capacitor.

7. The amplifier circuit according to claim 6, wherein
the unit amplifier further includes
a third parallel resistor which is connected in parallel with the third series capacitor, and
a fourth parallel resistor which is connected in parallel with the fourth series capacitor.

8. The amplifier circuit according to claim 7, wherein
the unit amplifier further includes
a first connection resistor which is connected to a third control terminal of the third transistor, and
a second connection resistor which is connected to a fourth control terminal of the fourth transistor.

9. The amplifier circuit according to claim 8, wherein
the unit amplifier further includes
a first connection capacitor which is connected to the third control terminal of the third transistor, and
a second connection capacitor which is connected to the fourth control terminal of the fourth transistor.

10. The amplifier circuit according to claim 7, wherein
the unit amplifier further includes
a first bypass resistor which is connected between the first control terminal of the first transistor and a first grounded terminal, and
a second bypass resistor which is connected between the second control terminal of the second transistor and a second grounded terminal.

11. The amplifier circuit according to claim 10, wherein
a resistance value of the third parallel resistor is equal to a resistance value of the first bypass resistor, and
a resistance value of the fourth parallel resistor is equal to a resistance value of the second bypass resistor.

12. The amplifier circuit according to claim 1, wherein
the unit amplifier further includes
a fifth transistor which is connected between the first transistor and the fourth transistor, and the first output transmission path, and
a sixth transistor which is connected between the second transistor and the third transistor, and the second output transmission path.

13. The amplifier circuit according to claim 12, wherein
the unit amplifier further includes
a third connection resistor which is connected to a fifth control terminal of the fifth transistor,
a third connection capacitor which is connected to the fifth control terminal of the fifth transistor,
a fourth connection resistor which is connected to a sixth control terminal of the sixth transistor, and
a fourth connection capacitor which is connected to the sixth control terminal of the sixth transistor.

14. The amplifier circuit according to claim 1, wherein
the unit amplifier further includes
a seventh transistor which is connected between the first transistor and the first output transmission path,
an eighth transistor which is connected between the second transistor and the second output transmission path,
a ninth transistor which is connected between the third transistor and the second output transmission path, and
a tenth transistor which is connected between the fourth transistor and the first output transmission path.

15. The amplifier circuit according to claim 14, wherein
the unit amplifier further includes
a fifth connection resistor which is connected to a seventh control terminal of the seventh transistor,
a fifth connection capacitor which is connected to the seventh control terminal of the seventh transistor,
a sixth connection resistor which is connected to an eighth control terminal of the eighth transistor,
a sixth connection capacitor which is connected to the eighth control terminal of the eighth transistor,
a seventh connection resistor which is connected to a ninth control terminal of the ninth transistor,
a seventh connection capacitor which is connected to the ninth control terminal of the ninth transistor,
an eighth connection resistor which is connected to a tenth control terminal of the tenth transistor, and
an eighth connection capacitor which is connected to the tenth control terminal of the tenth transistor.

16. The amplifier circuit according to claim 2, wherein
the unit amplifier further includes
a third series capacitor which is connected in series with the first control terminal of the first transistor, and
a fourth series capacitor which is connected in series with the second control terminal of the second transistor.
